(19) United States
(12) Patent Application Publication
(10) Pub. No.: US 2011/0220187 A1
(43) Pub. Date: Sep. 15, 2011

(54) Junction Module for A Building Integrated Photovoltaic System

(76) Inventors: Feng WANG, Shanghai (CN); Xiaoqun CHEN, Shanghai (CN); Chunfu ZHOU, Shanghai (CN); Zhenhua ZHANG, Shanghai (CN)

(21) Appl. No.: 13/048,302

(22) Filed: Mar. 15, 2011

(30) Foreign Application Priority Data
Mar. 15, 2010 (CN) 201010127185.4

(51) Int. Cl. H01L 31/02; H01L 31/05

(52) U.S. Cl. 136/252

(57) ABSTRACT

The invention discloses a junction module for a building integrated photovoltaic system, including a housing being formed with at least one chamber enclosed by a first sidewall and having a base for disposing the at least one chamber on and a cover for covering an opening of the at least one chamber. The cover has a second sidewall enclosing an outer surface of the first sidewall of the at least one chamber and constituting a part of an outer wall of the junction module. Accordingly, the cover does not occupy any space of the chamber, and it can ensure that the electrical components in the chamber have enough large clearance and creepage distance, which improves the electrical safety of the junction module without increasing the size of it.

### CROSS-REFERENCE TO RELATED APPLICATION

This application claims priority under 35 U.S.C. §119 to Chinese Patent Application No. 201010127185.4 filed on Mar. 15, 2010.

### FIELD OF THE INVENTION

The invention relates to the field of the building integrated photovoltaic (BIPV) technology, and in particular, relates to a junction module for a building integrated photovoltaic system.

### BACKGROUND

Since solar energy is a renewable resource, converting solar energy into electric energy saves the resource of energy and mitigates increasing demands on power supply, and reduces environmental pollution as well. Thereby, this technology receives much attention and interest from the public. For example, in a common and conventional method of utilizing solar energy, a solar cell panel is assembled on a roof of a building by a bracket, and a junction module is generally disposed at a backside of the assembly.

A new solar energy utilizing technology, called “building integrated photovoltaic technology (BIPV)” has been brought forward recently, in which the solar cell (photovoltaic) product is integrated into a part of the building, such as a sunlight roof, a window and curtain wall glass, hence the integrated part could provide electricity while providing daylight or protection from wind, rain.

FIG. 8 shows a cross section view of a conventional junction module for the building integrated photovoltaic system. A creepage distance d′ of the conventional junction module is indicated by a solid line, and a clearance g′ of the conventional junction module is indicated by a dash line. The bottom of the junction module is insulated, therefore, herein the creepage distance d′ is defined as a minimum distance along an inner insulation surface of the junction module from an inner conductor to a portion of the junction module that a hand can contact from outside, and the clearance g′ generally is defined as a minimum distance of an air gap between an inner conductor and a portion of the junction module that a hand can contact from outside. In a field of the solar junction module, there is a strict safe standard on the creepage distance and the clearance, that is, the creepage distance must be greater than 20 mm, and the clearance must be greater than 14 mm.

In the conventional junction module for a building integrated photovoltaic system, a housing of the junction module is formed with a chamber to receive electrical components. A sidewall of a cover is inserted into the chamber and enclosed by the sidewall of the chamber. In this way, the side wall of the chamber is exposed outside and constitutes a part of an outer wall of the housing of the junction module.

However, in the case where the sidewall of the cover is inserted into the chamber, it is difficult to reduce the size of the junction module while maintaining the creepage distance and the clearance to satisfy the safety standard. Accordingly, in order to meet the safety standard, generally, an increase in the size of the junction module is required to increase the creepage distance and the clearance. In the field of the building integrated photovoltaic system, however, users and manufacturers desire minimizing the size of the junction module.

Furthermore, in the conventional junction module shown in FIG. 8, a bus bar of a solar cell panel is generally soldered on an inner conductive component of the junction module, and is sealed by potting a gel. In this case, once the bus bar of the solar cell panel is fixedly soldered on the inner conductive component of the junction module, they cannot be separated. Thereby, it is not convenient to change or replace the junction module. Furthermore, it increases the cost and difficulty of assembly. Accordingly, it would be desirable to provide a junction module whose size can be minimized while maintaining the creepage distance and the clearance to satisfy with the safety standards. It would also be advantageous to provide a junction module which can be easily mounted, replaced and manufactured.

### SUMMARY

The present invention has been made to overcome or alleviate at least one aspect of the above mentioned disadvantages.

According to the claimed invention, a junction module for a building integrated photovoltaic system includes a housing being formed with at least one chamber enclosed by a first sidewall, a base for disposing the at least one chamber on, and a cover for covering an opening of the at least one chamber, wherein the cover has a second sidewall enclosing an outer surface of the first sidewall of the at least one chamber and constituting a part of an outer wall of the junction module.

### BRIEF DESCRIPTION OF THE DRAWINGS

The present invention is illustrated in greater detail below by exemplary embodiments with reference to the attached drawings, in which:

FIG. 1 is a perspective view of a junction module for BIPV with a cover according to the invention;

FIG. 2 is a perspective view of the junction module with the cover opened;

FIG. 3 is a perspective view of the junction module with the cover opened and the inner electrical components exposed;

FIG. 4 is a cross sectional view of the junction module of FIG. 3;

FIG. 5 is an exposed view of the junction module of FIG. 4;

FIG. 6 is a perspective view of the junction module with an outer connector connected;

FIG. 7 is a cross sectional view of the junction module showing the clearance and the creepage distance; and

FIG. 8 is a cross section view of a conventional junction module showing the clearance and the creepage distance.

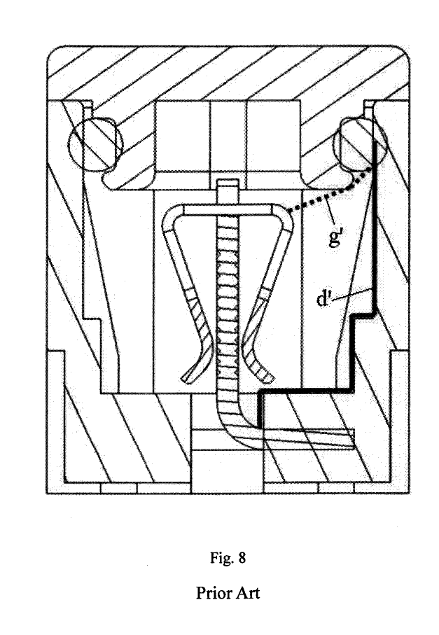

### DETAILED DESCRIPTION OF THE EMBODIMENT(S)

The invention is explained in greater detail below with reference to the drawings, wherein like reference numerals refer to the like elements. The invention may, however, be embodied in many different forms and should not be construed as being limited to the embodiments set forth herein; rather, these embodiments are provided so that the description will be thorough and complete, and will fully convey the concept of the invention to those skilled in the art.

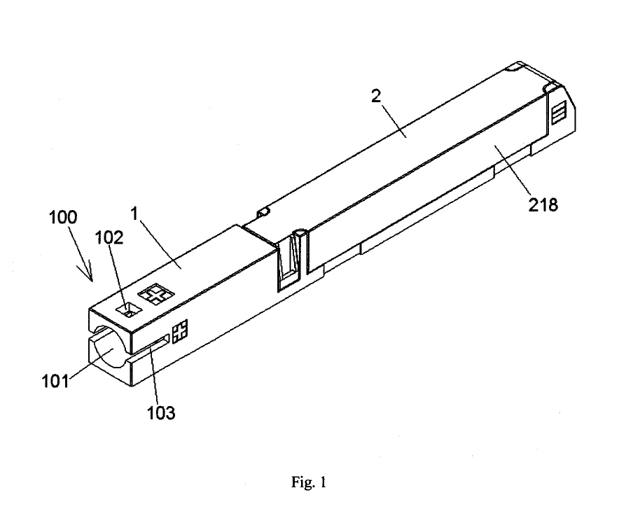

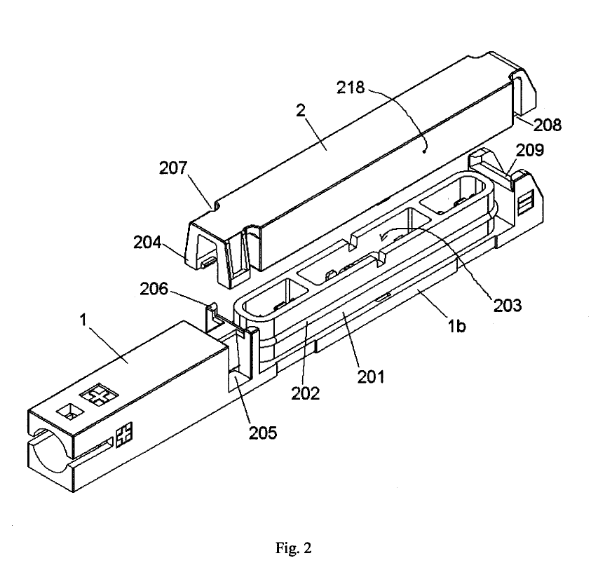

FIGS. 1 and 2 illustrate a junction module for a building integrated photovoltaic system (BIPV) according to the invention with a cover closed and opened, respectively. The junction module 100 for BIPV includes a housing 1 having a cover 2 and a base lb. Inner electrical components are enclosed in the cover 2. The housing 1 further includes an insert opening 101, a window 102, and elongated slot 103 formed in the front end of the housing 1 for receiving an outer connector, respectively. Each of the individual elements of the junction module 100 will now be described in greater detail.

The cover 2 is used for covering or closing of inner electrical components in the junction module 100. The inner electrical components are received within three chambers 203 that are disposed side by side inside the housing 1. Here, the number of chambers 203 is not limited to the embodiment shown in FIGS. 1 and 2, and the number of chambers 203 may be changed as required, for example, the housing 1 may have one chamber 203, two chambers 203 or more than three chambers 203. The chamber 203 includes a first sidewall 201 and a ring seal 202 enclosed and attached to the outer surface of the first sidewall 201, as shown in FIG. 2.

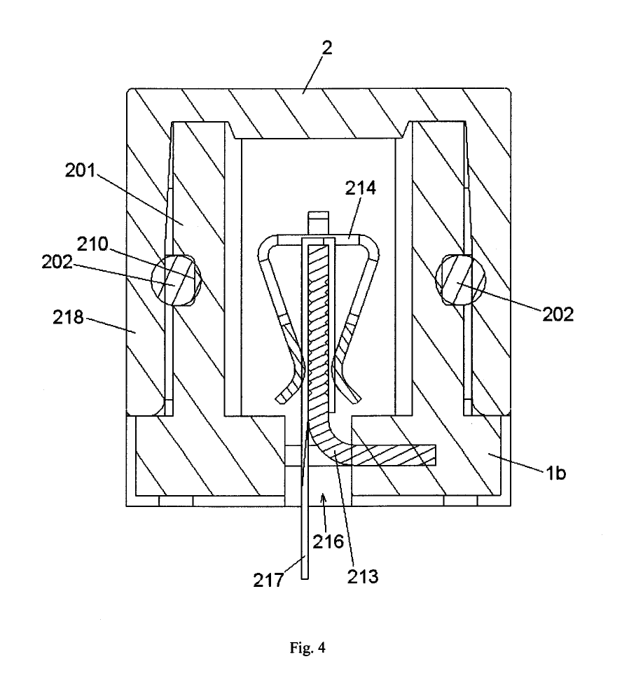

The cover 2 includes a second sidewall 218, a snapping portion 204 with a recess 207 formed at a front end of the cover 2, respectively, and a slot 208 formed at a rear end of the cover 2. On the base 1b of the housing 1 are neck portions 205 formed in the front portion thereof and a protruding post 206 extended upright from in the front portion. The three chambers 203 are disposed in the middle portion of the base lb, and a protruding rib 209 is disposed in the rear portion of the base 1b. When the junction module 100 is closed, the snapping portion 204 is inserted and fastened into the neck portion 205 and the recess 207 receives the protruding post 206 at a front end of the cover 2, while the slot 208 receives a protruding rib 209 at a rear end of the cover 2. Thus, engagement of the cover 2 with the base 1b is enhanced and the cover 2 is assembled to the base 1b in a detachable manner. The second sidewall 218 is located outside of the sidewall 201 of the chambers 203 and constitutes a part of an outer wall of a rear portion of the housing 1 when the junction module 100 is closed (shown in FIG. 4).

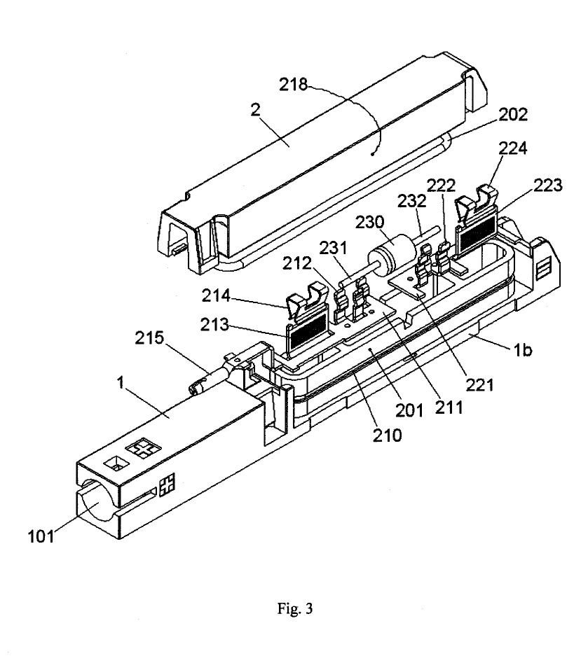

FIGS. 3 and 4 illustrate the inner electrical components received in the chambers 203. A ring groove 210 is formed on the outer surface of the first sidewall 201 of the chambers 203 and encircles the first sidewall 201, and a ring seal 202 (also refer to FIG. 2) is fitted into the ring groove 210. As shown in FIG. 4, after the cover 2 is assembled, the ring seal 202 is sandwiched between the first sidewall 201 of the chamber 203 and the second sidewall 218 of the cover 2. In this embodiment of the invention, the ring seal 202 can improve the sealing performance between the first sidewall 201 of the chamber 203 and the second sidewall 218 of the cover 2.

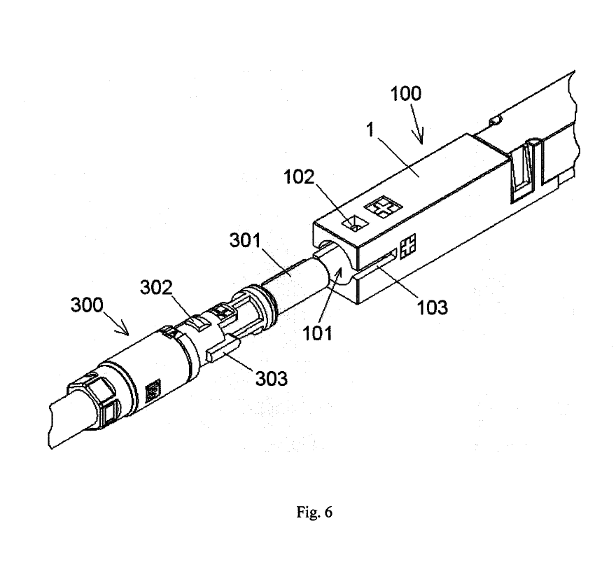

Referring to FIG. 3, an inner connector is accommodated in the chambers 203. The inner connector includes a diode 230, a first conductive plate 211, one electrode (for example, the anode) of a solar panel (not illustrated) and a second conductive plate 221. One end of the first conductive plate 211 is electrically connected to one end 231 of the diode 230, and the other end of the first conductive plate 211 is electrically connected to an insertion terminal 301 of an outer connector 300 through the insert hole 101 (shown in FIG. 6). One end of the second conductive plate 221 is electrically connected to the other end 232 of the diode 230, and the other end of the second conductive plate 221 is electrically connected to the other electrode (for example, the cathode) of the solar panel.

The first conductive plate 211 includes first elastic contacts 212 at the one end thereof, the one end 231 of the diode 230 is elastically held between the first elastic contacts 212 to achieve an electrical connection between the diode 230 and the first conductive plate 211. The second conductive plate 221 includes second elastic contacts 222 at the one end thereof The other end 232 of the diode 230 is elastically held between the second elastic contacts 222 to achieve an electrical connection between the diode 230 and the second conductive plate 221.

The diode 230 is electrically connected to the conductive plates 211, 221 in a detachable manner. The diode 230, the first conductive plate 211 and the second conductive plate 221 are disposed in three separate chambers 203, respectively.

Referring to FIG. 4, the first conductive plate 211 further includes a first web 213 at the other end thereof, a bus bar 217 of the one electrode of the solar panel is sandwiched on the first web 213 of the first conductive plate 211 by a first elastic clamp 214 to achieve an electrical connection between the first conductive plate 211 and the one electrode of the solar panel. The second conductive plate 221 further includes a second web 223 at the other end thereof, a bus bar 217 of the other electrode of the solar panel is sandwiched on the second web 223 of the second conductive plate 221 by a second elastic clamp 224 to achieve an electrical connection between the second conductive plate 221 and the other electrode of the solar panel.

The bus bars 217 of two electrodes of the solar panel are electrically connected to the webs 213, 223 of the first and second conductive plates 211, 221 in a detachable manner.

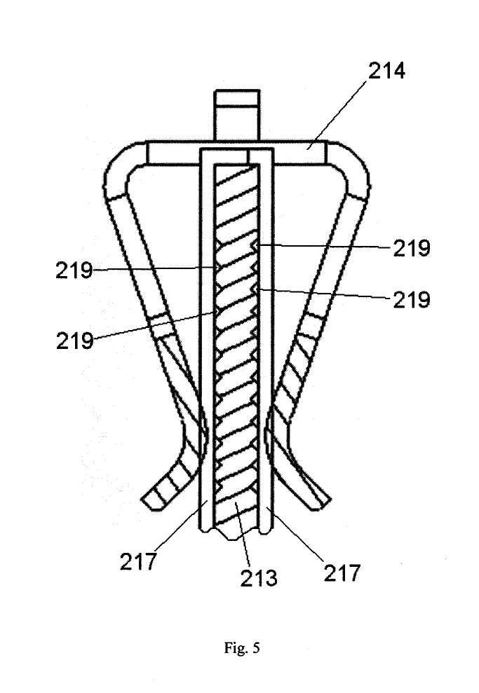

FIG. 5 shows the bus bar of the solar panel being elastically sandwiched on the web by an elastic clamp shown in FIG. 4. As shown in FIG. 5, plural elongated grooves 219 are formed in surfaces of at least one of the first and second webs 213, 223 to increase contact friction force between the bus bar 217 and surfaces of the at least one web 213, 223. Referring to FIG. 3, the plural elongated grooves 219 may form a grid pattern on the surfaces of the first and second webs 213, 223. In this sliding between the bus bar 217 and the webs 213, 223 is reduced, and the electrical contact reliability therebetween is improved.

FIG. 6 shows the junction module connected to an outer connector. The chambers 203 are formed in the rear portion of the housing 1, and the insertion opening 101, through which an insertion terminal 301 of an outer connector 300 is inserted, is formed in a front portion of the housing 1. The junction module 100 may be engaged with the outer connector 300 in a detachable manner.

Referring to FIGS. 3 and 6, the first conductive plate 211 is further formed with a connection terminal 215 at the other end thereof, the connection terminal 215 of the first conductive plate 211 extends into the insertion hole 101 of the housing 1 to be electrically connected to the insertion terminal 301 of the outer connector 300 inserted through the insertion hole 101 to achieve an electrical connection of the conductive plate 211 to the outer connector 300.

A protruding portion 302 is formed on the outer connector 300, as shown in FIG. 6, and the window 102 is formed in the housing 1 of the junction module 100 to be fitted with the protruding portion 302 of the outer connector 300, so that the outer connector 300 can be mechanically engaged to the housing 1 of the junction module 100. An elongated protruding bar 303 is formed on the outer connector 300, and the elongated slot 103 is formed in the housing 1 of the junction module 100 to be fitted with the elongated protruding bar 303 of the outer connector 300, so that the outer connector 300 can be further stably engaged with the housing 1 of the junction module 100.

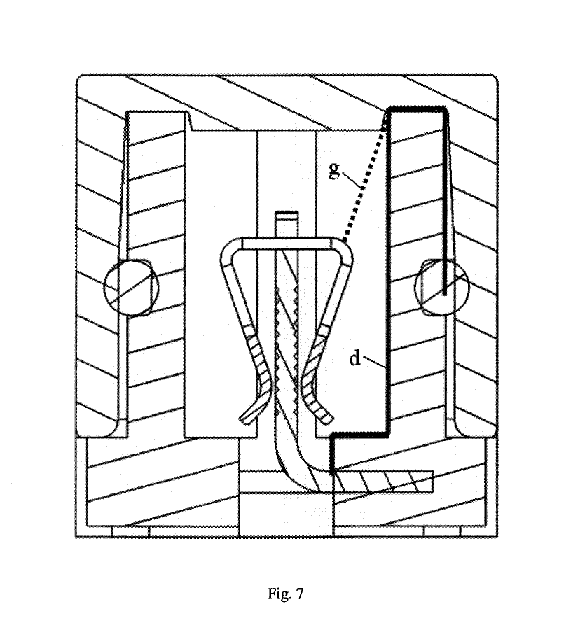

As shown in FIG. 7, the sidewall 218 of the cover 2 encloses the outer surface of the sidewall 201 of the chamber 203 and constituting a part of the outer wall of the junction module. Accordingly, the creepage distance d and the clearance g runs over the top of the sidewall 201 of the chamber 203 and extends to the ring seal 202.

Advantageously, where the junction module of the present invention and the conventional junction module have a same size, the junction module of the present invention has a larger creepage distance d and a larger clearance g than the conventional junction module.

Although several embodiments have been shown and described, it would be appreciated by those skilled in the art that various changes or modifications may be made in these embodiments without departing from the principles and spirit of the disclosure, the scope of which is defined in the claims and their equivalents. It should be noted that the term “comprising” does not exclude other elements or steps and the “a” or “an” does not exclude a plurality. It should also be noted that reference signs in the claims shall not be construed as limiting the scope of the claims.

What is claimed is:

1. A junction module for a building integrated photovoltaic system, comprising:
a housing being formed with at least one chamber enclosed by a first sidewall;
a base for disposing the at least one chamber on; and
a cover for covering an opening of the at least one chamber,
wherein the cover has a second sidewall enclosing an outer surface of the first sidewall of the at least one chamber and constituting a part of an outer wall of the junction module.

2. The junction module according to claim 1, wherein the cover further comprises:
a snapping portion formed at a front end thereof, for being fastened into a neck portion formed in a front portion of the base of the housing.

3. The junction module according to claim 2, wherein the cover further comprises:
a recess formed at a front end of the cover, for receiving a protruding post extending upright from the base of the housing.

4. The junction module according to claim 3, wherein the cover further comprises:
a slot formed at a rear end of the cover, for receiving a protruding rib of the base of the housing.

5. The junction module according to claim 1, wherein
a ring groove is formed in the outer surface of the first sidewall of the at least one chamber and encircles around the first sidewall of the chamber; and
a ring seal is fitted in the ring groove and sandwiched between the first sidewall of the at least one chamber and the second sidewall of the cover.

6. The junction module according to claim 1, wherein
the at least one chamber is formed at a rear portion of the housing; and
an insertion opening, through which an insertion terminal of an outer connector is inserted, is formed in a front portion of the housing.

7. The junction module according to claim 6, wherein
an inner connector is accommodated in the at least one chamber, the inner connector comprising:
a diode;
a first conductive plate, one end of the first conductive plate being electrically connected to one end of the diode, and the other end of the first conductive plate being electrically connected to an insertion terminal of an outer connector and one electrode of a solar panel; and
a second conductive plate, one end of the second conductive plate being electrically connected to the other end of the diode, and the other end of the second conductive plate being electrically connected to the other electrode of the solar panel.

8. The junction module according to claim 7, wherein
the first conductive plate is formed with first elastic contacts at the one end of the first conductive plate, the one end of the diode being elastically held between the first elastic contacts to achieve an electrical connection between the diode and the first conductive plate; and
the second conductive plate is formed with second elastic contacts at the one end the second conductive plate, the other end of the diode being elastically held between the second elastic contacts to achieve an electrical connection between the diode and the second conductive plate.

9. The junction module according to claim 8, wherein
the first conductive plate is formed with a first web at the other end of the first conductive plate, a bus bar of the one electrode of the solar panel is sandwiched on the first web of the first conductive plate by a first elastic clamp to achieve an electrical connection between the first conductive plate and the one electrode of the solar panel; and
the second conductive plate is formed with a second web at the other end of the second conductive plate, a bus bar of the other electrode of the solar panel is sandwiched on the second web of the second conductive plate by a second elastic clamp to achieve an electrical connection between the second conductive plate and the other electrode of the solar panel.

10. The junction module according to claim 9, wherein
a grid of grooves are formed in surfaces of at least one of the first and second webs to increase a contact friction force between the bus bar and surfaces of the at least one web.

11. The junction module according to claim 10, wherein
the first conductive plate is further formed with a connection terminal at the other end the first conductive plate, the connection terminal of the first conductive plate extends into the insertion hole of the housing to be electrically connected to the insertion terminal of the outer connector inserted through the insertion hole.

12. The junction module according to claim 1, wherein
the housing is formed with three chambers in which the first conductive plate, the second conductive plate and the diode are disposed, respectively.

13. The junction module according to claim 6, wherein
the outer connector is snapped into the housing through an insert opening being formed in the front portion of the housing by a snapping formation therebetween.

14. The junction module according to claim 13, wherein the snapping formation comprises:
a protruding portion being formed on the outer connector; and
a window being formed in the front portion of the housing to be fitted with a protruding portion of the outer connector.

15. The junction module according to claim 14, wherein the snapping formation further comprises:
an elongated protruding bar being formed on the outer connector; and
an elongated slot being formed in the front portion of the housing to be fitted with the elongated protruding bar of the outer connector.
